(19) United States
(12) Patent Application Publication
(10) Pub. No.: US 2026/0136540 A1
(43) Pub. Date: May 14, 2026

(54) SEMICONDUCTOR DEVICE

(71) Applicant: Samsung Electronics Co., Ltd., Suwon-si (KR)

(72) Inventors: Hyeonggyu Kim, Suwon-si (KR); Yihwan Kim, Suwon-si (KR); Jihye Lee, Suwon-si (KR); Namjin Cho, Suwon-si (KR)

(21) Appl. No.: 19/339,101

(22) Filed: Sep. 24, 2025

(30) Foreign Application Priority Data
Nov. 11, 2024 (KR) 10-2024-0159569

(51) Int. Cl. H10B 12/00; H10D 64/66

(52) U.S. Cl. CPC H10B 12/482; H10B 12/34; H10B 12/488; H10B 12/50; H10D 64/663

(57) ABSTRACT

A semiconductor device includes a substrate including a first active region, a word line intersecting the first active region and extending in a first direction, and a bit line intersecting the word line and extending in a second direction, in which the bit line includes a first bit line conductive layer including a semiconductor material, a second bit line conductive layer on the first bit line conductive layer, a third bit line conductive layer on the second bit line conductive layer, and a fourth bit line conductive layer on the third bit line conductive layer, the fourth bit line conductive layer includes a metallic material, the third bit line conductive layer includes a compound of the metallic material and a first semiconductor material.

### CROSS-REFERENCE TO RELATED APPLICATION

This application claims priority to Korean Patent Application No. 10-2024-0159569, filed in the Korean Intellectual Property Office on Nov. 11, 2024, the contents of which are incorporated herein by reference in its entirety.

### BACKGROUND

A semiconductor is a material that belongs to a middle region between a conductor and an insulator, and refers to a material that conducts an electricity under predetermined conditions. Using these semiconductor materials, various semiconductor devices may be manufactured, such as memory devices. These semiconductor devices may be used in various electronic devices.

With the trend toward miniaturization and higher integration of electronic devices, there is a need to finely form the patterns that make up semiconductor devices. As the width of these fine patterns gradually decreases, a film stress increases, which may cause a warpage of the semiconductor device.

### SUMMARY

In general, the present disclosure is directed toward a semiconductor device that improves warpage problems by relieving the film stress.

According to some implementations, the present disclosure is directed to a semiconductor device that includes a substrate including a first active region, a word line intersecting the first active region and extending in a first direction, and a bit line intersecting the word line and extending in a second direction, wherein the bit line includes a first bit line conductive layer including a semiconductor material, a second bit line conductive layer on the first bit line conductive layer, a third bit line conductive layer on the second bit line conductive layer, and a fourth bit line conductive layer on the third bit line conductive layer, wherein the fourth bit line conductive layer includes a metallic material, wherein the third bit line conductive layer includes a compound of the metallic material and a first semiconductor material, and wherein an atom ratio of the metallic material to the first semiconductor material included in the third bit line conductive layer is greater than 1:3 and less than 1:1.

According to some implementations, the present disclosure is directed to a semiconductor device that includes a substrate including a first active region, a word line intersecting the first active region and extending in a first direction, and a bit line intersecting the word line and extending in a second direction, wherein the bit line includes a first semiconductor layer including a semiconductor material, a first metal layer on the first semiconductor layer and including a metallic material, a first interface layer between the first semiconductor layer and the first metal layer, and a first metal silicide layer covering a lower surface of the first metal layer, wherein the first metal silicide layer includes a same metallic material as a material of the first metal layer, and wherein the first metal silicide layer has a greater number of atoms of silicon than a number of atoms of the metallic material.

According to some implementations, the present disclosure is directed to a semiconductor device that includes a substrate including an active region, a word line intersecting the active region and extending in a first direction, and a bit line intersecting the word line and extending in a second direction, wherein the bit line includes a first bit line conductive layer including a semiconductor material, a second bit line conductive layer on the first bit line conductive layer, a third bit line conductive layer on the second bit line conductive layer, and a fourth bit line conductive layer on the third bit line conductive layer, wherein the fourth bit line conductive layer includes a metallic material, wherein the third bit line conductive layer includes a compound of the metallic material and a first semiconductor material, and wherein the second bit line conductive layer includes a material different from a material of the first semiconductor material.

According to some implementations, the present disclosure is directed to improving a warpage problem by relieving a film stress of the semiconductor device.

### BRIEF DESCRIPTION OF THE DRAWINGS

Example implementations will be more clearly understood from the following detailed description, taken in conjunction with the accompanying drawings.

FIG. 1 is a schematic top plan view of an example of a semiconductor device according to some implementations.

FIG. 2 is an enlarged top plan view of R1 in FIG. 1 according to some implementations.

FIG. 3 is an enlarged top plan view of R2 in FIG. 1 according to some implementations.

FIG. 4 is a cross-sectional view taken along a line A-A′ of FIG. 2 according to some implementations.

FIG. 5 is a cross-sectional view taken along a line B-B′ of FIG. 2 according to some implementations.

FIG. 6 is an enlarged cross-sectional view of R3 in FIG. 5 according to some implementations.

FIG. 7 is a cross-sectional view taken along a line C-C′ of FIG. 3 according to some implementations.

FIG. 8 is a cross-sectional view taken along a line A-A′ of FIG. 2 according to some implementations.

FIG. 9 is a cross-sectional view taken along a line B-B′ of FIG. 2 according to some implementations.

FIG. 10 is an enlarged cross-sectional view of R4 in FIG. 9 according to some implementations.

FIG. 11 is a cross-sectional view taken along a line C-C′ of FIG. 3 according to some implementations.

### DETAILED DESCRIPTION

Hereinafter, example implementations will be explained in detail with reference to the accompanying drawings.

Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, the thicknesses of some layers and areas are exaggerated.

It will be understood that when an element, such as a layer, film, region, or substrate, is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “in a plan view” means viewing a target portion from the top, and the phrase “in a cross-sectional view” means viewing a cross-section formed by vertically cutting a target portion from the side.

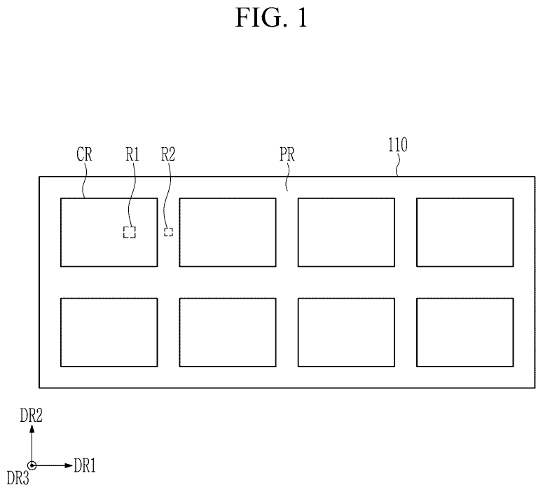

Hereinafter, a semiconductor device according to an embodiment is described below with reference to FIG. 1 to FIG. 6.

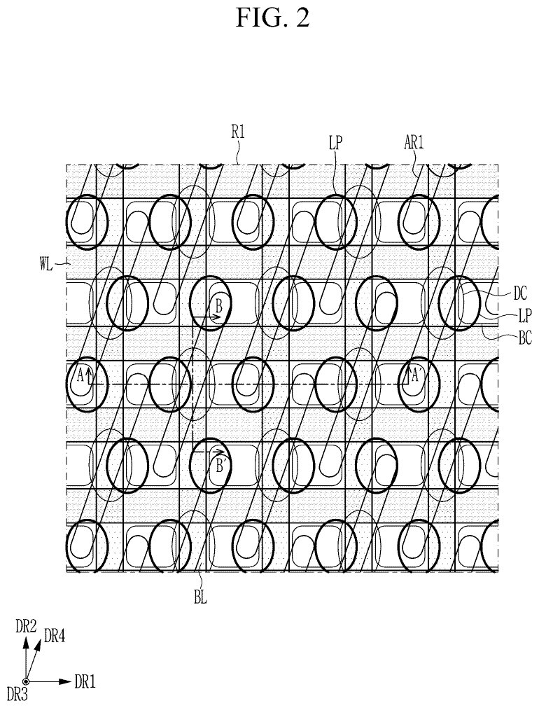

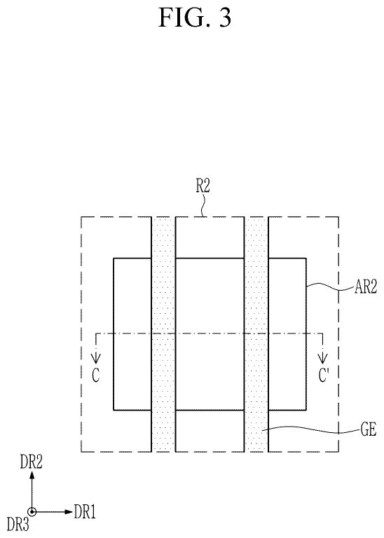

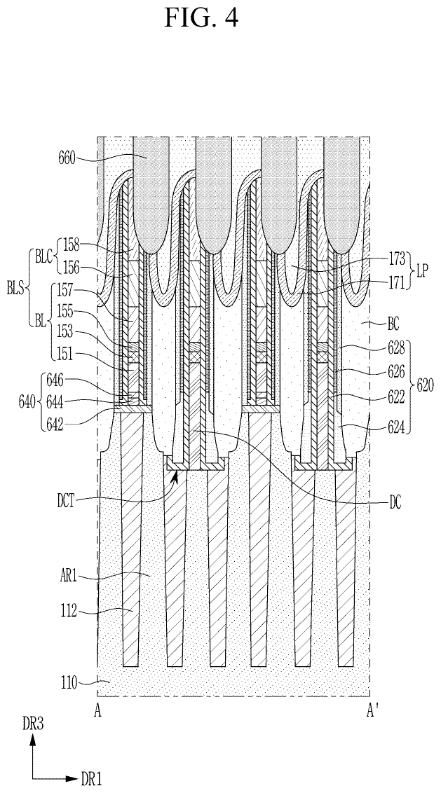

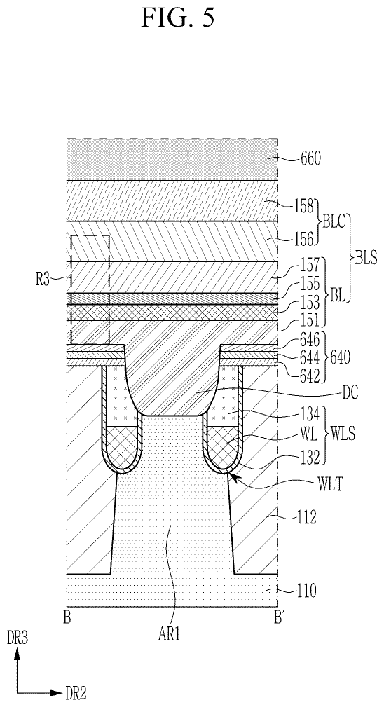

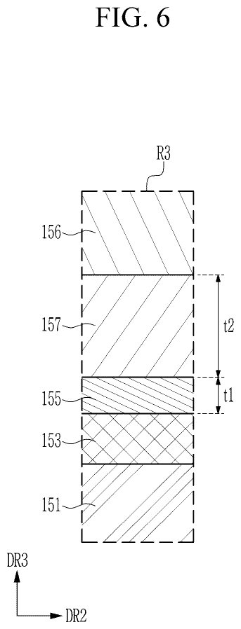

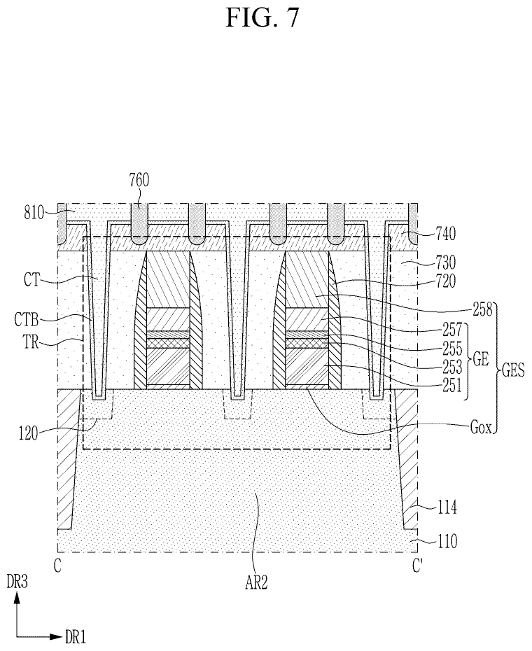

FIG. 1 is a schematic top plan view of an example of a semiconductor device according to some implementations. FIG. 2 is an enlarged top plan view of R1 in FIG. 1 according to some implementations. FIG. 3 is an enlarged top plan view of R2 in FIG. 1 according to some implementations. FIG. 4 is a cross-sectional view taken along a line A-A′ of FIG. 2 according to some implementations. FIG. 5 is a cross-sectional view taken along a line B-B′ of FIG. 2 according to some implementations. FIG. 6 is an enlarged cross-sectional view of R3 in FIG. 5 according to some implementations. FIG. 7 is a cross-sectional view taken along a line C-C′ of FIG. 3 according to some implementations.

In FIGS. 1 to 3, a semiconductor device may include a substrate 110. The substrate 110 may include a cell region CR and a peripheral circuit region PR. The substrate 110 may include a semiconductor material. For example, the substrate 110 may include a Group IV semiconductor, a Group III-V compound semiconductor, a Group II-VI compound semiconductor, etc. For example, the substrate 110 may include a semiconductor such as Si, Ge, or a compound semiconductor such as SiGe, SiC, GaAs, InAs, or InP. For example, the substrate 110 may be a silicon on insulator (SOI) substrate or a germanium on insulator (GOI) substrate. However, the material of the substrate 110 is not limited to this and may be changed in various ways. The substrate 110 may have an upper surface parallel to a first direction DR1 and a second direction DR2, and may have a thickness parallel to a third direction DR3 perpendicular to the first direction DR1 and the second direction DR2.

The cell region CR may be a region where memory cells are formed. For example, the memory cells may be arranged in an array form in the cell region CR. The substrate 110 may include a plurality of cell regions CR, and the plurality of cell regions CR may be spaced apart and arranged along the first direction DR1 parallel to the upper surface of the substrate 110 and the second direction DR2 intersecting the first direction DR1. For example, the second direction DR2 may be a direction perpendicular to the first direction DR1. FIG. 1 shows eight cell regions CR, but this is only an example, and the number of plurality of cell regions CR may vary.

The peripheral circuit region PR may be a region where peripheral circuit elements that drive the memory cells are formed. The peripheral circuit region PR may be positioned around the cell region CR. The peripheral circuit region PR may surround the cell region CR. The peripheral circuit region PR may be positioned between the plurality of cell regions CR separated in the first direction DR1 and the second direction DR2.

The cell region CR may include a first active region AR1. The first active region AR1 may have a bar shape extending along a fourth direction DR4 oblique to the first direction DR1 and second direction DR2. The fourth direction DR4 may be parallel to the upper surface of the substrate 110 and may be positioned on the same plane as the first direction DR1 and the second direction DR2. The fourth direction DR4 may form an acute angle with the first direction DR1 and the second direction DR2, respectively.

The cell region CR may include the plurality of first active regions AR1. The plurality of first active regions AR1 may extend in the direction parallel to each other. The plurality of first active regions AR1 may be positioned with a predetermined interval apart along the fourth direction DR4 and the first direction DR1. The center of one first active region AR1 may be adjacent to the end of another first active region AR1 in the first direction DR1. The end of one side of one first active region AR1 may be adjacent to the end of the other side of another first active region AR1 in the first direction DR1. However, the shape or arrangement of the first active region AR1 is not limited to this and may be changed in various ways.

In the cell region CR, a word line WL may be positioned that crosses the first active region AR1 and extends in the first direction DR1. The word line WL may overlap the first active region AR1 and act as a gate electrode. The single word line WL may overlap the plurality of first active regions AR1 adjacent along the first direction DR1. The plurality of word lines WL may be positioned in the cell region CR. The plurality of word lines WL may extend parallel along the first direction DR1 and may be spaced apart from each other with a regular interval along the second direction DR2.

Each of the plurality of first active regions AR1 may overlap and intersect two word lines WL. Each first active region AR1 may be divided into three parts by two word lines WL. At this time, the center portion of the first active region AR1 positioned between two word lines WL may be a part connected to a bit line BL described later, and the ends of both sides of the first active region AR1 positioned on the outside of two word lines WL may be a part connected to a capacitor.

In the cell region CR, the bit line BL may be positioned that intersects the first active region AR1 and the word line WL and extends in the second direction. At this time, the bit line BL may vertically intersect the word line WL. The bit line BL may be positioned above the word line WL. The single bit line BL may overlap the plurality of adjacent first active regions AR1 along the second direction DR2. The bit line BL may be connected to the first active region AR1 through a bit line contact DC. Each of the plurality of first active regions AR1 may be connected to one bit line BL. The center of the first active region AR1 may be connected to the bit line BL. However, this is only one example, and the connection form of the bit line BL and the first active region AR1 may be changed in various ways. The plurality of bit lines BL may be positioned in the cell region CR. The plurality of bit lines BL may extend parallel along the second direction DR2 and may be spaced apart from each other with a regular interval along the first direction DR1.

The peripheral circuit region PR may include a second active region AR2. A gate electrode GE intersecting the second active region AR2 and extending in the second direction DR2 may be positioned in the peripheral circuit region PR. The gate electrode GE may overlap the second active region AR2. The plurality of gate electrodes GE may be positioned in the peripheral circuit region PR. The plurality of gate electrodes GE may extend in parallel along the second direction DR2 and may be spaced apart from each other with a constant interval along the first direction DR1.

In some implementations, the second active region AR2 may intersect and overlap two gate electrodes GE. For example, one second active region AR2 may be controlled by two gate electrode GE. A source region and a drain region may be positioned on both ends of the second active region AR2 positioned on both sides of two gate electrode GE along the first direction DR1, respectively. For example, a transistor positioned in the peripheral circuit region PR may include two gate electrodes GE and the source region and the drain region positioned on both sides of two gate electrodes GE.

However, the present disclosure is not limited to this, and the second active region AR2 may also intersect and overlap one gate electrode GE. At this time, the second active region AR2 may be controlled by one gate electrode GE. For example, the transistor positioned in the peripheral circuit region PR may include one gate electrode GE.

The semiconductor device illustrated in FIGS. 4 to 7 is centered on the bit line structure BLS of the cell region CR and the gate structure GES of the peripheral circuit region PR, and the semiconductor device may further include other components in addition to the components illustrated in FIGS. 4 to 7 through subsequent processes. For example, the capacitor may be further included in the cell region CR of a semiconductor device.

In FIGS. 4 and 5, the first active region AR1 may be defined by a first element isolation layer 112 positioned in the substrate 110. The plurality of first active regions AR1 may be positioned within the substrate 110, and the plurality of first active regions AR1 are separated from each other by the first element isolation layer 112. The first element isolation layer 112 may be positioned on both sides of each first active region AR1.

The first element isolation layer 112 may have a shallow trench isolation (STI) structure with excellent element isolation characteristics. The first element isolation layer 112 may be composed of silicon oxide, silicon nitride, or a combination thereof. However, the material of the first element isolation layer 112 is not limited to this and may be changed in various ways. The first element isolation layer 112 may be composed of a single layer or multiple layers. The first element isolation layer 112 may be composed of a single material or may include two or more types of insulating materials.

A word line trench WLT may be formed in substrate 110, and a word line structure WLS may be positioned within the word line trench WLT. That is, the word line structure WLS may have a form embedded within the substrate 110. Some parts of the word line trench WLT may be positioned on the first active region AR1, and some parts may be positioned on the first element isolation layer 112. The word line structure WLS may include a gate insulating layer 132, a word line WL positioned on the gate insulating layer 132, and a word line capping layer 134 positioned on the word line WL. However, the position, shape, structure, etc. of the word line structure WLS are not limited to this and may be changed in various ways.

The gate insulating layer 132 may be positioned within the word line trench WLT. The gate insulating layer 132 may be conformally formed on the interior wall surface of the word line trench WLT. The gate insulating layer 132 may include silicon oxide, silicon nitride, silicon oxynitride, a high dielectric constant (high-k) material having a dielectric constant higher than silicon oxide, or a combination thereof. However, the position, shape, material, etc. of the gate insulating layer 132 are not limited to this and may be changed in various ways.

The word line WL may be positioned on the gate insulating layer 132. The side and lower surfaces of the word line WL may be surrounded by the gate insulating layer 132. The gate insulating layer 132 is positioned between the word line WL and the first active region AR1. Therefore, the word line WL may not be in close contact with the first active region AR1. The word line WL may include Ti, TiN, Ta, TaN, W, WN, TiSiN, WSiN, polysilicon, or a combination thereof. However, the position, shape, material, etc. of the word line WL are not limited to this and may be changed in various ways.

The word line capping layer 134 may be positioned on the word line WL. The word line capping layer 134 may cover the entire upper surface of the word line WL. The lower surface of the word line capping layer 134 may be in contact with the word line WL. The side surface of the word line capping layer 134 may be covered by the gate insulating layer 132. The word line capping layer 134 may include silicon oxide, silicon nitride, silicon oxynitride, or a combination thereof. However, the position, shape, material, etc. of word line capping layer 134 are not limited to this and may be changed in various ways.

The word line WL may be positioned on both sides of the bit line contact DC, and the word line WL and the bit line contact DC may overlap in the third direction DR3. The upper surface of the word line WL may be positioned at the lower level than the lower surface of the bit line contact DC. The word line capping layer 134 may be positioned between the word line WL and the bit line contact DC. Accordingly, the area between the word line WL and the bit line contact DC may be insulated by the word line capping layer 134. However, the position relationship between the word line WL and the bit line contact DC is not limited to this and may be changed in various ways.

The bit line contact trench DCT may be formed in the substrate 110, and the bit line contact DC may be positioned within the bit line contact trench DCT. The bit line contact trench DCT may be positioned on the first active region AR1, and the bit line contact DC may be connected to the first active region AR1. The bit line contact DC may be directly connected to the first active region AR1. The bit line contact DC may overlap the first active region AR1 in the third direction DR3. The bit line contact DC may include a conductive material. For example, the bit line contact DC may include impurity doped polysilicon, or metals, such as W, Mo, Au, Cu, Al, Ni, Co, etc.

The bit line BL may be positioned on the substrate 110 and the bit line contact DC. In some implementations, the bit line BL may include a first bit line conductive layer 151, a second bit line conductive layer 153, a third bit line conductive layer 155, and a fourth bit line conductive layer 157 that are sequentially stacked. The first bit line conductive layer 151, the second bit line conductive layer 153, the third bit line conductive layer 155, and the fourth bit line conductive layer 157 may include a conductive material. The first bit line conductive layer 151, the second bit line conductive layer 153, the third bit line conductive layer 155, and the fourth bit line conductive layer 157 are described in more detail later.

The bit line BL may be in directly contact with the bit line contact DC. The first bit line conductive layer 151 of the bit line BL may be in contact with the side surface of the bit line contact DC, and the second bit line conductive layer 153 of the bit line BL may be in contact with the upper surface of the bit line contact DC. The bit line contact DC may be positioned between the first active region AR1 and the bit line BL, and be electrically connected the first active region AR1 and the bit line BL. That is, the bit line BL may be connected to the first active region AR1 through the bit line contact DC. Among the conductive layers constituting the bit line BL, the first bit line conductive layer 151 and the bit line contact DC may include the same material. For example, the first bit line conductive layer 151 and the bit line contact DC may include impurity-doped polysilicon. However, it is not limited thereto, and the first bit line conductive layer 151 and the bit line contact DC may include different materials.

The bit line capping layer BLC may be positioned on the bit line BL. The bit line capping layer BLC may include a first bit line capping layer 156 and a second bit line capping layer 158 that are sequentially stacked. However, it is not limited to this, and the number of the layers constituting the bit line capping layer BLC may be changed in various ways. The bit line capping layer BLC may also be made of a single layer. The bit line BL and the bit line capping layer BLC may form the bit line structure BLS. The bit line capping layer BLC may overlap the bit line BL and the bit line contact DC in the third direction DR3. The bit line BL and the bit line contact DC may be patterned using the bit line capping layer BLC as a mask. The planar shape of the bit line BL may be substantially the same as the bit line capping layer BLC. The bit line capping layer BLC is shown in contact with the fourth bit line conductive layer 157 of the bit line BL, but is not limited thereto. Another layer may be positioned between the bit line capping layer BLC and the fourth bit line conductive layer 157 of the bit line BL. The bit line capping layer BLC may include silicon nitride, silicon oxynitride, silicon oxide, or a combination thereof. However, the material of the bit line capping layer BLC is not limited to this and may be changed in various ways.

A spacer structure 620 may be positioned on both sides of the bit line structure BLS. The spacer structure 620 may cover the side surfaces of the bit line capping layer BLC, the bit line BL, and the bit line contact DC. The spacer structure 620 may extend approximately in the third direction DR3 along the side of the bit line structure BLS. At least a portion of the spacer structure 620 may be positioned within the bit line contact trench DCT. Within the bit line contact trench DCT, the spacer structure 620 may be positioned on both sides of the bit line contact DC.

The spacer structure 620 may be formed of multiple layers consisting of a combination of different types of insulating materials. The spacer structure 620 may include a first spacer 622, a second spacer 624, a third spacer 626, and a fourth spacer 628. However, it is not limited to this, and the number and structure of the layers constituting the spacer structure 620 may be changed in various ways. The spacer structure 620 may be formed of a single layer. In some implementations, the spacer structure 620 may be formed as an air spacer structure surrounded between spacers and having an air space.

The first spacer 622 may cover the sides of the bit line structure BLS and the bit line contact DC. Within the bit line contact trench DCT, the first spacer 622 may be formed to cover the bottom and side surfaces of the bit line contact trench DCT.

The second spacer 624 may be positioned on the first spacer 622. The lower surface and side surfaces of the second spacer 624 may be surrounded by the first spacer 622. The second spacer 624 may be positioned within the bit line contact trench DCT. The second spacer 624 may be formed to fill the bit line contact trench DCT. The second spacer 624 may be positioned on both sides of the bit line contact DC within the bit line contact trench DCT.

The third spacer 626 may be positioned on the first spacer 622 and the second spacer 624. The third spacer 626 may overlap the first spacer 622 along the first direction DR1 and overlap the second spacer 624 in the third direction DR3. The third spacer 626 may extend approximately in the third direction DR3 along the side of the first spacer 622. The third spacer 626 may extend parallel to the first spacer 622. The lower surface and side surfaces of the third spacer 626 may be surrounded by the first spacer 622, the second spacer 624, and the fourth spacer 628.

The fourth spacer 628 may be positioned on the second spacer 624 and the third spacer 626. The fourth spacer 628 may overlap the second spacer 624 along the third direction DR3, and overlap the third spacer 626 along the first direction DR1. The fourth spacer 628 may extend roughly in the third direction DR3 along the side of the third spacer 626. The fourth spacer 628 may extend parallel to the first spacer 622 and the third spacer 626. The lower surface and side surfaces of the fourth spacer 628 may be surrounded by the second spacer 624 and the third spacer 626.

The spacer structure 620 may include an insulating material. In some implementations, at least some of the first spacer 622, the second spacer 624, the third spacer 626, and the fourth spacer 628 may include the same material. In some implementations, at least some of the first spacer 622, the second spacer 624, the third spacer 626, and the fourth spacer 628 may include different materials. Each of the first spacer 622, the second spacer 624, the third spacer 626, and the fourth spacer 628 may include at least one of silicon nitride, silicon oxynitride, silicon oxide, silicon carbonate oxide, silicon carbonization nitride, silicon carbonate nitride, and a combination thereof. For example, the first spacer 622 and the third spacer 626 may include silicon oxide, and the second spacer 624 and the fourth spacer 628 may include silicon nitride. However, the material of the spacer structure 620 is not limited to this and may be changed in various ways.

The insulation layer 640 may be positioned below the bit line BL. The insulation layer 640 may be positioned between the bit line BL and the first element isolation layer 112. Between bit line BL and first active region AR1, the bit line contact DC may be positioned, and the insulation layer 640 may not be positioned. The insulation layer 640 may be positioned on the word line structure WLS. The insulation layer 640 may be positioned between the word line structure WLS and the bit line BL. The insulation layer 640 may include a first insulation layer 642, a second insulation layer 644, and a third insulation layer 646 that are sequentially stacked. At least some of the first insulation layer 642, the second insulation layer 644, and the third insulation layer 646 may have different widths. The widths of the second insulation layer 644 and the third insulation layer 646 may be substantially the same. The widths of the second insulation layer 644 and the third insulation layer 646 may be substantially the same as the widths of the bit line BL and the bit line capping layer BLC. The width of the first insulation layer 642 may be different from the widths of the second insulation layer 644 and the third insulation layer 646. The width of the first insulation layer 642 may be wider than the widths of the second insulation layer 644 and the third insulation layer 646. Accordingly, the width of the first insulation layer 642 may be wider than the width of the bit line BL.

The insulation layer 640 may be covered by the spacer structure 620. For example, the upper surface of the first insulation layer 642 may be covered by the first spacer 622. The sides of the second insulation layer 644 and the third insulation layer 646 may be covered by the first spacer 622.

The insulation layer 640 may include an insulating material. Each of the first insulation layer 642, the second insulation layer 644, and the third insulation layer 646 may include an insulating material. For example, the first insulation layer 642 may include silicon oxide. The second insulation layer 644 may include a material having a different etch selectivity from the first insulation layer 642. For example, the second insulation layer 644 may include silicon nitride. For example, the third insulation layer 646 may include silicon oxide or silicon nitride. However, the structure, material, etc. of the insulation layer 640 are not limited to this and may be changed in various ways.

A storage contact BC may be positioned between the plurality of bit lines BL. The semiconductor device may include a plurality of storage contacts BC. In FIG. 2, the plurality of storage contacts BC may be arranged spaced apart from each other along the first direction DR1 and the second direction DR2. For example, the plurality of storage contacts BC may be arranged to be spaced apart from each other along the second direction DR2 between two adjacent bit lines BL. Additionally, the plurality of storage contacts BC may be arranged to be spaced apart from each other along the first direction DR1 between two adjacent word lines WL. However, the arrangement form of the plurality of storage contacts BC is not limited to this and may be changed in various ways.

At least some of the storage contact BC may overlap the first active region AR1 in the third direction DR3, and some of the others may overlap the first element isolation layer 112 in the third direction DR3. The storage contact BC may be electrically connected to the first active region AR1. The storage contact BC may be in directly contact with the first active region AR1. At least part of the lower surface and the side surface of the storage contact BC are surrounded by the first active region AR1. However, this is not limited to this, and another layer may be positioned between the storage contact BC and the first active region AR1, and the storage contact BC may be connected to the first active region AR1 through another layer.

The storage contact BC may include a conductive material. For example, the storage contact BC may include impurity-doped polysilicon, but is not limited thereto.

The spacer structure 620 may be positioned on both sides of the storage contact BC. The spacer structure 620 may be positioned between the storage contact BC and the bit line BL. For example, one surface of the storage contact BC may be in contact with the fourth spacer 628 and the first active region AR1, and the other surface of the storage contact BC may be in contact with the fourth spacer 628 and the second spacer 624. The lower surface of the storage contact BC may be in contact with the first spacer 622. However, this is only one example, and the position relationship between the storage contact BC and the spacer structure 620 may be changed in various ways.

The upper surface of the storage contact BC may be positioned at a lower level than the upper surface of bit line BL, and the lower surface of storage contact BC may be positioned at a higher level than the lower surface of the bit line contact DC. However, it is not limited to this, and the position relationship between the storage contact BC, the bit line BL, and the bit line contact DC may be changed in various ways.

A landing pad LP may be positioned on the storage contact BC. The semiconductor device may include the plurality of landing pads LP. In FIG. 2, the plurality of landing pads LP may be arranged spaced apart from each other along the first direction DR1 and the second direction DR2. The plurality of landing pads LP may be arranged in a row along the first direction DR1. The plurality of landing pads LP may be arranged in a zigzag shape along the second direction DR2. For example, the bit line BL may be placed alternately on the left and right with reference to the reference. However, the arrangement of the plurality of landing pad LPs is not limited to this and may be changed in various ways.

The landing pad LP may cover the upper surface of the storage contact BC and overlap the storage contact BC in the third direction DR3. At least part of the landing pad LP may overlap the spacer structure 620 in the third direction DR3, and may also overlap the bit line BL in the third direction DR3. The upper surface of the landing pad LP may be positioned at a higher level than the upper surface of the bit line capping layer BLC. The spacer structure 620 may be positioned on both sides of the landing pad LP. The spacer structure 620 may be positioned between the landing pad LP and the bit line BL, and between the landing pad LP and the bit line capping layer BLC. The landing pad LP may be electrically connected to the storage contact BC. The landing pad LP may be in directly contact with the storage contact BC. The landing pad LP may be electrically connected to the first active region AR1 through the storage contact BC.

The landing pad LP may include a conductive barrier layer 171 and a conductive layer 173. The conductive layer 173 may be positioned on the conductive barrier layer 171. The conductive barrier layer 171 is shown in contact with the storage contact BC, but is not limited thereto. Another layer may be positioned between the conductive barrier layer 171 and the storage contact BC. For example, a metal silicide layer may be further positioned between the conductive barrier layer 171 and the storage contact BC.

The conductive barrier layer 171 may cover the entire upper surface of the storage contact BC. The upper surface of the storage contact BC may have a concave shape, and the conductive barrier layer 171 may have a concave shape along the upper surface of the storage contact BC. The spacer structure 620 may be positioned on both sides of the conductive barrier layer 171. For example, the conductive barrier layer 171 may cover the upper surfaces of the fourth spacer 628, the third spacer 626, and the first spacer 622. The conductive barrier layer 171 may be in contact with the fourth spacer 628, the third spacer 626, and the first spacer 622. The conductive barrier layer 171 may include Ti, TiN, or a combination thereof. However, the shape and material of the conductive barrier layer 171 are not limited thereto and may be changed in various ways.

The lower surface of the conductive layer 173 may be in contact with the conductive barrier layer 171. At least a portion of the lower surface and the side surface of the conductive layer 173 may be surrounded by the conductive barrier layer 171. The conductive barrier layer 171 may be positioned between the conductive layer 173 and the spacer structure 620. The conductive layer 173 may include a metal, a metal nitride, impurity-doped polysilicon, or a combination thereof. For example, the conductive layer 173 may include W. However, the shape and material of the conductive layer 173 are not limited to this and may be changed in various ways.

An insulating pattern 660 may be positioned on the plurality of landing pads LP. The insulating pattern 660 may be formed to fill the space between the plurality of landing pads LP. The plurality of landing pads LP may be separated from each other by the insulating pattern 660. The landing pad LP may include silicon nitride, silicon oxynitride, silicon oxide, or a combination thereof. The insulating pattern 660 may be composed of a single layer or multiple layers. For example, the insulating pattern 660 may include a first material layer and a second material layer that are stacked. At this time, the first material layer may include a low dielectric constant (low-k) material having a low dielectric constant, such as silicon oxide, SiOH, or SiOC, and the second material layer may include silicon nitride or silicon oxynitride. However, the shape and material of the insulating pattern 660 are not limited to this and may be changed in various ways.

In some implementations, a capacitor structure may be positioned on the landing pad LP. The capacitor structure may include a first capacitor electrode, a second capacitor electrode, and a dielectric layer positioned between the first capacitor electrode and the second capacitor electrode. The first capacitor electrode may be in contact with the landing pad LP and may be electrically connected to the landing pad LP. The capacitor structure may be electrically connected to the first active region AR1 through the landing pad LP and the storage contact BC. The semiconductor device may include a plurality of capacitor structure. A first capacitor electrode may be positioned on each landing pad LP, and the plurality of first capacitor electrodes may be positioned so as to be separated from each other. The same voltage may be applied to the second capacitor electrode of the plurality of capacitor structures, and the second capacitor electrode of the plurality of capacitor structures may be formed as one piece. The dielectric layer of the plurality of capacitor structures may be formed integrally.

Hereinafter, the first bit line conductive layer 151, the second bit line conductive layer 153, the third bit line conductive layer 155, and the fourth bit line conductive layer 157 of the bit line BL are described in detail later.

The first bit line conductive layer 151 may be positioned on the insulation layer 640. In the cross-section according to the second direction DR2 and the third direction DR3, the first bit line conductive layer 151 may be positioned on both sides of the bit line contact DC. The first bit line conductive layer 151 may be positioned on both sides of the bit line contact DC.

The first bit line conductive layer 151 may include the same material as the bit line contact DC, but is not limited thereto. In some implementations, the first bit line conductive layer 151 may include a semiconductor material. For example, the first bit line conductive layer 151 may include impurity-doped polysilicon. The first bit line conductive layer 151 may be otherwise referred to as a semiconductor layer.

In some implementations, the second bit line conductive layer 153 may be positioned on the first bit line conductive layer 151. The second bit line conductive layer 153 may be positioned on the bit line contact DC. The second bit line conductive layer 153 may cover the upper surface of the first bit line conductive layer 151 and the upper surface of the bit line contact DC. The second bit line conductive layer 153 may be positioned between the first bit line conductive layer 151 and the fourth bit line conductive layer 157. The second bit line conductive layer 153 may be positioned between the first bit line conductive layer 151 and the third bit line conductive layer 155.

The second bit line conductive layer 153 may be composed of a single layer or multiple layers. For example, the second bit line conductive layer 153 may include an adhesive layer and a barrier layer. The adhesive layer may play a role in increasing an adhesive strength (adhesion) with the third bit line conductive layer 155 and the fourth bit line conductive layer 157 positioned on the first bit line conductive layer 151 and the second bit line conductive layer 153. For example, the adhesive layer may include Ti, Ta, TiSi, TaSi, CoSi or a combination thereof, but is not limited thereto. The barrier layer may serve to prevent a metallic material included in the third bit line conductive layer 155 and the fourth bit line conductive layer 157 from penetrating into the first bit line conductive layer 151. For example, the barrier layer may include WN. The structure and material of the second bit line conductive layer 153 are not limited to the examples described above and may be changed in various ways. The second bit line conductive layer 153 may further include a predetermined layer (e.g., a resistance reducing layer) in addition to the adhesive layer and the barrier layer described above. The second bit line conductive layer 153 may be alternatively referred to as an interface layer.

In some implementations, the third bit line conductive layer 155 may be positioned on the second bit line conductive layer 153. The third bit line conductive layer 155 may cover the upper surface of the second bit line conductive layer 153. The third bit line conductive layer 155 may be positioned between the first bit line conductive layer 151 and the fourth bit line conductive layer 157. The third bit line conductive layer 155 may be positioned between the second bit line conductive layer 153 and the fourth bit line conductive layer 157.

A stress may be applied to the semiconductor device during the process of forming the plurality of layers on the substrate 110. For example, a stress (or a film stress) may be applied to the third bit line conductive layer 155 by a plurality of layers positioned between the substrate 110 and the fourth bit line conductive layer 157. For example, a compressive stress may be applied to the third bit line conductive layer 155 by a plurality of layers positioned between the substrate 110 and the fourth bit line conductive layer 157.

In some implementations, the direction of the stress applied to the fourth bit line conductive layer 157 by the third bit line conductive layer 155 may be an opposite direction of the direction of the stress applied to the fourth bit line conductive layer 157 by the plurality of layers positioned between the substrate 110 and the fourth bit line conductive layer 157. The plurality of layers positioned between the substrate 110 and the fourth bit line conductive layer 157 may include, for example, the word line structure WLS, the insulation layer 640, the first bit line conductive layer 151, and the second bit line conductive layer 153. For example, a compressive stress may be applied to the fourth bit line conductive layer 157 by the plurality of layers positioned between the substrate 110 and the fourth bit line conductive layer 157, and the compressive stress applied to the fourth bit line conductive layer 157 may be relieved by the third bit line conductive layer 155.

The above-described implementations are not limited to the type of the stress applied to the fourth bit line conductive layer 157. For example, a tensile stress may be applied to the fourth bit line conductive layer 157 by the plurality of layers positioned between the substrate 110 and the fourth bit line conductive layer 157, and the tensile stress applied to the fourth bit line conductive layer 157 may be relieved by the third bit line conductive layer 155.

In some implementations, the third bit line conductive layer 155 may include a metal semiconductor compound. The third bit line conductive layer 155 may include a compound of a metallic material and a semiconductor material. For example, the semiconductor material may be Si, but is not limited thereto. In some implementations, the third bit line conductive layer 155 may include a metal silicide material. The third bit line conductive layer 155 may alternatively be referred to as a metal silicide layer.

The fourth bit line conductive layer 157 may be positioned on the third bit line conductive layer 155. The fourth bit line conductive layer 157 may cover the upper surface of the third bit line conductive layer 155. The fourth bit line conductive layer 157 may include a low resistance material. The fourth bit line conductive layer 157 may include a metallic material. The fourth bit line conductive layer 157 may alternatively be referred to as a metal layer.

The fourth bit line conductive layer 157 may include a first metallic material, and the third bit line conductive layer 155 may include a compound of the first metallic material and the first semiconductor material. That is, the third bit line conductive layer 155 may include the same metallic material as the fourth bit line conductive layer 157. In some implementations, the third bit line conductive layer 155 may include a metal silicide material of the same metallic material as the fourth bit line conductive layer 157. For example, the first metallic material may be W, Mo, Au, Cu, Al, Ni, or Co, but is not limited thereto. For example, the fourth bit line conductive layer 157 may include W, and the third bit line conductive layer 155 may include WₓSi_{y}.

The third bit line conductive layer 155 may have a greater number of silicon atoms than metallic material atoms. That is, the number of atoms of the first semiconductor material included in the third bit line conductive layer 155 may be greater than the number of atoms of the first metallic material included in the third bit line conductive layer 155. In some implementations, an atom ratio (x:y) of the first metallic material to the first semiconductor material included in the third bit line conductive layer 155 may be greater than 1:3 to less than 1:1. At this time, the atom ratio of the first metallic material to the first semiconductor material does not only mean the composition ratio of the compound of the first metallic material to the first semiconductor material included in the third bit line conductive layer 155, but also means the ratio of the entire number of atoms of the first metallic material included in the third bit line conductive layer 155 to the entire number of atoms of the first semiconductor material included in the third bit line conductive layer 155. That is, it does not mean that the third bit line conductive layer 155 includes only compounds in which atoms of the first metallic material and atoms of the first semiconductor material are bonded in a ratio of more than 1:3 and less than 1:1, but rather that the average bonding ratio between atoms of the first metallic material and atoms of the first semiconductor material included in the third bit line conductive layer 155 is more than 1:1 and less than 1:3. For example, the third bit line conductive layer 155 may include a compound in which atoms of the first metallic material and atoms of the first semiconductor material are combined in a ratio of 1:1 or less or 1:3 or greater. For example, the third bit line conductive layer 155 may include WSi₂ or WSi_{1.75}, or may include WSi or WSi₃. However, the average x:y of various WₓSi_{y} included in the third bit line conductive layer 155 may be greater than 1:3 and less than 1:1.

When the atom ratio (x:y) of the first metallic material to the first semiconductor material included in the third bit line conductive layer 155 is greater than 1:1, the stress applied to the fourth bit line conductive layer 157 is not relieved as desired. If the atom ratio (x:y) of the first metallic material to the first semiconductor material included in the third bit line conductive layer 155 is 1:3 or less, the resistance of the bit line BL may increase and the electric characteristics of the semiconductor device may deteriorate. In some implementations, the atom ratio (x:y) of the first metallic material to the first semiconductor material included in the third bit line conductive layer 155 may be greater than 1:3 and less than 1:1, and preferably, greater than or equal to 1:2.7 and less than or equal to 1:1.5. For example, the atom ratio (x:y) of the first metallic material to the first semiconductor material included in the third bit line conductive layer 155 may be 1:1.75.

The second bit line conductive layer 153 may include a material different from the first semiconductor material. The second bit line conductive layer 153 may not include the first semiconductor material. For example, the second bit line conductive layer 153 may not include silicon. That is, the third bit line conductive layer 155 is not formed by the metallic material reacting with silicon positioned below the metallic material. According to some implementations, the third bit line conductive layer 155 may be formed by a method of supplying a metallic material and a silicon into a chamber and applying an energy to react the metallic material and the silicon, and depositing a metal silicide material generated by the reaction of the metallic material and the silicon on the second bit line conductive layer 153. In a comparative example, a metallic material may be deposited on silicon and annealed to form a metal silicide material. According to a comparative example, the atom ratio of the metallic material to the silicon material included in the metal silicide material may be greater than 1:1. That is, the atom ratio of the metallic material to the silicon included in the metal silicide material according to the comparative example may be greater than the atom ratio of the metallic material to the silicon included in the third bit line conductive layer 155 according to the embodiment.

In FIG. 6, the thickness ratio (t1:t2) of the third bit line conductive layer 155 to the fourth bit line conductive layer 157 may be greater than 1:6 and less than 1:3. When the thickness ratio (t1:t2) of the third bit line conductive layer 155 to the fourth bit line conductive layer 157 is greater than 1:3, the resistance of the bit line BL may increase and the electric characteristics of the semiconductor device may deteriorate. When the thickness ratio (t1:t2) of the third bit line conductive layer 155 to the fourth bit line conductive layer 157 is 1:6 or less, the stress applied to the fourth bit line conductive layer 157 is not relieved as desired.

In FIG. 7, the second active region AR2 may be defined by the second element isolation layer 114 positioned within the substrate 110. The plurality of second active regions AR2 may be positioned within the substrate 110, and the plurality of second active regions AR2 are separated from each other by the second element isolation layer 114. The element isolation layer 114 may be positioned on both sides of each second active region AR2.

The second element isolation layer 114 may have a shallow trench isolation (STI) structure with excellent element isolation characteristics. The second element isolation layer 114 may be composed of silicon oxide, silicon nitride, or a combination thereof. However, the material of the second element isolation layer 114 is not limited to this and may be changed in various ways. The second element isolation layer 114 may be composed of a single layer or multiple layers. The second element isolation layer 114 may be composed of a single material or may include two or more types of insulating materials.

Extrinsic regions 120 may be formed on the substrate 110. The extrinsic regions 120 may include impurities of a different conductivity type than the impurities doped in the second active region AR2. The extrinsic regions 120 may be a pair of source regions and drain regions that are electrically connected or disconnected depending on the voltage applied to the gate structure GES described below. The extrinsic regions 120 may be separated from each other via the gate structure GES. Each of the extrinsic regions 120 may be positioned adjacent to both sides of the gate structure GES. In some implementations, the gate structure GES and the extrinsic regions 120 may form a transistor TR. For example, the extrinsic regions 120 may be p-type impurities regions, and the transistor TR formed by the gate structure GES and the extrinsic regions 120 may be a PMOS transistor. At this time, the extrinsic regions 120 may include, for example, at least one of B, Al, Ga, and In. As another example, the extrinsic regions 120 may be n-type impurities regions, and the transistor TR formed by the gate structure GES and the extrinsic regions 120 may be an NMOS transistor. At this time, the extrinsic regions 120 may include, for example, at least one of P, As, and Sb.

The gate structure GES may be positioned on the second active region AR2. The gate structure GES may extend in a direction parallel to the upper surface of the substrate 110. For example, the gate structure GES may have a shape of a bar on a plane. The gate structure GES may include a peripheral circuit gate insulating layer Gox, a gate electrode GE, and a gate capping layer 258. The peripheral circuit gate insulating layer Gox may be interposed between the upper surface of the substrate 110 and the gate electrode GE. The gate capping layer 258 may be disposed on the upper surface of the gate electrode GE.

The peripheral circuit gate insulating layer Gox may be positioned between the second active region AR2 and the gate electrode GE. The gate electrode GE may be separated from the second active region AR2 by the peripheral circuit gate insulating layer Gox. The peripheral circuit gate insulating layer Gox may include silicon oxide, silicon nitride, silicon oxynitride, a high dielectric constant (high-k) material having a dielectric constant higher than silicon oxide, or a combination thereof. However, the material of the peripheral circuit gate insulating layer Gox is not limited to this and may be changed in various ways.

In some implementations, the gate electrode GE may include a first gate conductive layer 251, a second gate conductive layer 253, a third gate conductive layer 255, and a fourth gate conductive layer 257 that are sequentially stacked. The first gate conductive layer 251, the second gate conductive layer 253, the third gate conductive layer 255, and the fourth gate conductive layer 257 may include a conductive material. However, it is not limited to this, and the number and structure of the layers included in the gate electrode GE may be changed in various ways. For example, the gate electrode GE may further include a work function control layer positioned between the peripheral circuit gate insulating layer Gox and the first gate conductive layer 251. For example, the work function control layer may control the threshold voltage of a transistor TR.

In an embodiment, the gate electrode GE may be positioned in the same layer as the bit line BL and may include a layer including the same material. Here, positioning in the same layer as the bit line BL may mean that it is formed in the same process as each layer of the bit line BL.

In an embodiment, the first gate conductive layer 251 may be positioned in the same layer as the first bit line conductive layer 151. The first gate conductive layer 251 may be formed in the same process as the first bit line conductive layer 151. The first gate conductive layer 251 may include the same material as the first bit line conductive layer 151. The first gate conductive layer 251 may include a semiconductor material. For example, the first gate conductive layer 251 may include impurity-doped polysilicon. The first gate conductive layer 251 may be otherwise referred to as a semiconductor layer.

In an embodiment, the second gate conductive layer 253 may be positioned in the same layer as the second bit line conductive layer 153. The second gate conductive layer 253 may be formed in the same process as the second bit line conductive layer 153. In some implementations, the second gate conductive layer 253 may include the same material as the second bit line conductive layer 153. In some implementations, the second gate conductive layer 253 may include a material different from the semiconductor material included in the third gate conductive layer 255. The second gate conductive layer 253 may not include the semiconductor material included in the third gate conductive layer 255. For example, the second gate conductive layer 253 may not include Si. The second gate conductive layer 253 may be alternatively referred to as an interface layer.

The third gate conductive layer 255 may be positioned in the same layer as the third bit line conductive layer 155. The third gate conductive layer 255 may be formed in the same process as the third bit line conductive layer 155. The third gate conductive layer 255 may include the same material as the third bit line conductive layer 155. The third gate conductive layer 255 may include a semiconductor compound of the same metallic material as the fourth gate conductive layer 257. In some implementations, the third gate conductive layer 255 may include a silicide material of the same metallic material as the fourth gate conductive layer 257. The third gate conductive layer 255 may be alternatively referred to as a metal silicide layer.

The fourth gate conductive layer 257 may be positioned in the same layer as the fourth bit line conductive layer 157. The fourth gate conductive layer 257 may be formed in the same process as the fourth bit line conductive layer 157. The fourth gate conductive layer 257 may include the same material as the fourth bit line conductive layer 157. The fourth gate conductive layer 257 may include a metallic material. The fourth gate conductive layer 257 may alternatively be referred to as a metal layer.

The fourth gate conductive layer 257 may include a first metallic material, and the third gate conductive layer 255 may include a silicide material of the first metallic material. For example, the first metallic material may be W, Mo, Au, Cu, Al, Ni, or Co. For example, the fourth gate conductive layer 257 may include W, and the third gate conductive layer 255 may include WₐSi_{b}.

In the third gate conductive layer 255, the atom ratio a:b of the first metallic material to the first semiconductor material included in the third gate conductive layer 255 may be substantially the same as the atom ratio of the first metallic material to the first semiconductor material included in the third bit line conductive layer 155. In the third gate conductive layer 255, the atom ratio (a:b) of the first metallic material to the first semiconductor material included in the third gate conductive layer 255 may be greater than 1:3 to less than 1:1. At this time, the atom ratio of the first metallic material to the first semiconductor material does not only mean the composition ratio of the compound of the first metallic material to the first semiconductor material included in the third gate conductive layer 255, but also means the ratio of the entire number of atoms of the first metallic material included in the third gate conductive layer 255 to the entire number of atoms of the first semiconductor material included in the third gate conductive layer 255. That is, it does not mean that the third gate conductive layer 255 includes only compounds in which atoms of the first metallic material and atoms of the first semiconductor material are bonded in a ratio of more than 1:3 and less than 1:1, but rather that the average bonding ratio between atoms of the first metallic material and atoms of the first semiconductor material included in the third gate conductive layer 255 is more than 1:3 and less than 1:1. For example, the third gate conductive layer 255 may include a compound in which atoms of the first metallic material and atoms of the first semiconductor material are combined in a ratio of 1:1 or less or 1:3 or greater. For example, the third gate conductive layer 255 may include WSi₂ or WSi_{1.75}, or may include WSi or WSi₃. However, the average a:b of various WₐSi_{b} included in the third gate conductive layer 255 may be greater than 1:3 and less than 1:1.

When the atom ratio (a:b) of the first metallic material to the first semiconductor material included in the third gate conductive layer 255 is greater than 1:1, the stress applied to the fourth gate conductive layer 257 is not relieved as desired. If the atom ratio (a:b) of the first metallic material to the first semiconductor material included in the third gate conductive layer 255 is 1:3 or less, the resistance of the bit line BL may increase and the electric characteristics of the semiconductor device may deteriorate. In some implementations, the atom ratio (a:b) of the first metallic material to the first semiconductor material included in the third gate conductive layer 255 may be greater than 1:3 and less than 1:1, and preferably, greater than or equal to 1:2.7 and less than or equal to 1:1.5. For example, the atom ratio (a:b) of the first metallic material to the first semiconductor material included in the third gate conductive layer 255 may be 1:1.75.

In some implementations, the thickness ratio of the third gate conductive layer 255 to the fourth gate conductive layer 257 may be substantially the same as the thickness ratio of the third bit line conductive layer 155 to the fourth bit line conductive layer 157. In some implementations, the thickness ratio of the third gate conductive layer 255 to the fourth gate conductive layer 257 may be greater than 1:6 to less than 1:3. When the thickness ratio of the third gate conductive layer 255 to the fourth gate conductive layer 257 is greater than 1:3, the resistance of the gate electrode GE may increase, deteriorating the electric characteristics of the semiconductor device. When the thickness ratio of the third gate conductive layer 255 to the fourth gate conductive layer 257 is 1:6 or less, the stress applied to the fourth gate conductive layer 257 is not relieved as desired.

A gate capping layer 258 may be positioned on the gate electrode GE. In some implementations, the gate capping layer 258 may be positioned in the same layer as the first bit line capping layer 156. The gate capping layer 258 may be formed in the same process as the first bit line capping layer 156. The gate capping layer 258 may include the same material as the first bit line capping layer 156.

The gate capping layer 258 may overlap the gate electrode GE in the third direction DR3. The gate electrode GE may be patterned using the gate capping layer 258 as a mask. The planar shape of the gate electrode GE may be substantially the same as that of the gate capping layer 258. The gate capping layer 258 is shown as being in contact with the fourth gate conductive layer 257 of the gate electrode GE, but is not limited thereto. Another layer may be positioned between the gate capping layer 258 and the fourth gate conductive layer 257 of the gate electrode GE. The gate capping layer 258 may include silicon nitride, silicon oxynitride, silicon oxide, or a combination thereof. However, the material of gate capping layer 258 is not limited to this and may be changed in various ways.

A spacer 720 may be positioned on both sides of the gate structure GES. The spacer 720 may cover the side of the gate structure GES. The spacer 720 may extend approximately in the third direction DR3 along the side of the gate structure GES. The spacer 720 may have a thinner thickness (e.g., the width along first direction DR1) as it approaches the upper surface of the gate structure GES. The spacer 720 may be composed of a single layer or a multi-layer. The number and structure of layers that make up the spacer 720 may vary. The spacer 720 may include an insulating material. The spacer 720 may include at least one of silicon nitride, silicon oxynitride, silicon oxide, silicon carbon oxide, silicon carbonization nitride, silicon carbonate nitride, and a combination thereof. However, the material of the spacer 720 is not limited to this and may be changed in various ways.

The first interlayer insulating layer 730 may cover the side walls of the gate structure GES and may not cover the upper surface of the gate structure GES. The upper surface of the first interlayer insulating layer 730 may be coplanar with the upper surface of the gate structure GES. For example, the first interlayer insulating layer 730 may include silicon oxide. A second interlayer insulating layer 740 may be positioned on the first interlayer insulating layer 730. The lower surface of the second interlayer insulating layer 740 may cover the upper surface of the gate structure GES. For example, the second interlayer insulating layer 740 may include silicon nitride. However, it is not limited thereto, and the structure, material, etc. of the first interlayer insulating layer 730 and the second interlayer insulating layer 740 may be variously changed.

The peripheral circuit wiring 810 may be positioned on the second interlayer insulating layer 740. The peripheral circuit wiring 810 may be positioned in the same layer as the conductive layer 173 of the landing pad LP positioned in the cell region CR. The peripheral circuit wiring 810 may be formed in the same process as the conductive layer 173. The peripheral circuit wiring 810 may include the same material as the conductive layer 173. The peripheral circuit wiring 810 may be connected to the extrinsic regions 120 through a contacts via CT. The contact via CT and the peripheral circuit wiring 810 may include, for example, at least one of Cu, W, Al, Ta, and Ti. The contact via CT may be connected to the substrate 110 by penetrating the first interlayer insulating layer 730 and the second interlayer insulating layer 740. For example, the lower end of the contact via CT may be positioned at a level lower than the top surface of the substrate 110, but is not limited thereto. In some cases, the lower end of the contact via CT may be positioned at the same level as the upper surface of the substrate 110. The contact via CT may electrically connect the peripheral circuit wiring 810 and the extrinsic regions 120.

The contact barrier layer CTB may cover the surfaces of the peripheral circuit wiring 810 and the contact via CT. The contact barrier layer CTB may be provided between the lower surface of the peripheral circuit wiring 810 and the second interlayer insulating layer 740. The contact barrier layer CTB may be provided on the side surface and lower surface of the contact via CT. The contact barrier layer CTB may include a metal nitride. The contact barrier layer CTB may include, for example, one of TiN, TaN, and WN.

A trench having a predetermined depth from the upper surface of the second interlayer insulating layer 740 may be formed between the side walls of the peripheral circuit wirings 810. The lower end of the trench may be positioned at the level higher than the upper surface of the gate capping layer 258. For example, the trench may be placed where it vertically overlaps the gate structure GES or where it vertically overlaps the second active region AR2 between the gate structures GES. The wiring insulating pattern 760 may fill the trench. The wiring insulating pattern 760 may be positioned in the same layer as the insulating pattern 660 positioned in the cell region CR. The wiring insulating pattern 760 may be formed in the same process as insulating pattern 660. The wiring insulating pattern 760 may include the same material as insulating pattern 660. For example, the wiring insulating pattern 760 may include silicon nitride.

According to some implementations, the bit line BL positioned in the cell region CR of the semiconductor device may include a third bit line conductive layer 155 including a semiconductor compound of the same metallic material as the fourth bit line conductive layer 157 between the first bit line conductive layer 151 including the semiconductor material and the fourth bit line conductive layer 157 including the metallic material. For example, the third bit line conductive layer 155 may include a silicide material of the same metallic material as the fourth bit line conductive layer 157. The number of the atoms of the semiconductor material included in the third bit line conductive layer 155 may be greater than the number of the atoms of the metallic material included in the third bit line conductive layer 155. The atom ratio of the metallic material to the semiconductor material (e.g., Si) included in the third bit line conductive layer 155 may be greater than 1:3 and less than 1:1.

According to some implementations, the warpage problem may be improved by relieving film stress applied to the bit line BL without increasing the resistance of the bit line BL positioned in the cell region CR.

The gate electrode GE positioned in the peripheral circuit region PR of the semiconductor device according to an embodiment may include a layer positioned in the same layer and including the same material as the bit line BL positioned in the cell region CR. The third gate conductive layer 255 including the semiconductor compound of the same metallic material as the fourth gate conductive layer 257 may be included between the first gate conductive layer 251 including the semiconductor material and the fourth gate conductive layer 257 including the metallic material. For example, the third gate conductive layer 255 may include a silicide material of the same metallic material as the fourth gate conductive layer 257. The number of the atoms of the semiconductor material included in the third gate conductive layer 255 may be greater than the number of the atoms of the metallic material included in the third gate conductive layer 255. In some implementations, the atom ratio of the metallic material to the semiconductor material (e.g., Si) included in the third gate conductive layer 255 can be greater than 1:3 to less than 1:1. Preferably, the atom ratio (x:y) of the first metallic material to the first semiconductor material included in the third bit line conductive layer 155 may be 1:2.7 or more to 1:1.5 or less. For example, the atom ratio (x:y) of the first metallic material to the first semiconductor material included in the third bit line conductive layer 155 may be 1:1.75.

According to some implementations, the warpage problem may be improved by relieving the film stress applied to the gate electrode GE without increasing the resistance of the gate electrode GE positioned in the peripheral circuit region PR.

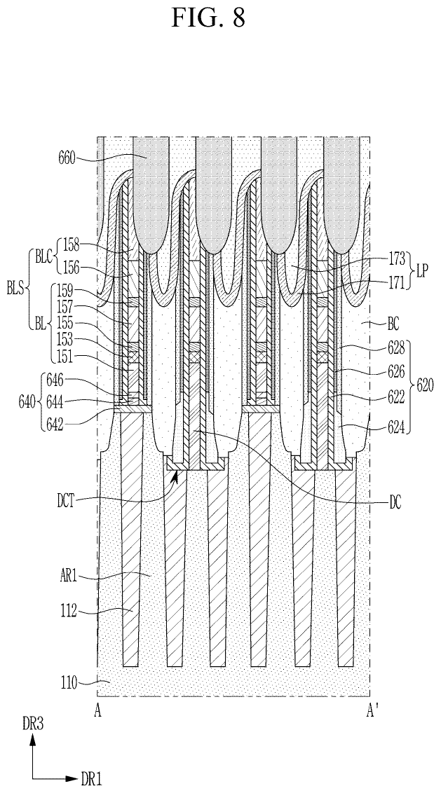

Below, variations of the implementations shown in FIG. 4 to FIG. 7 are described with reference to FIG. 8 to FIG. 11.

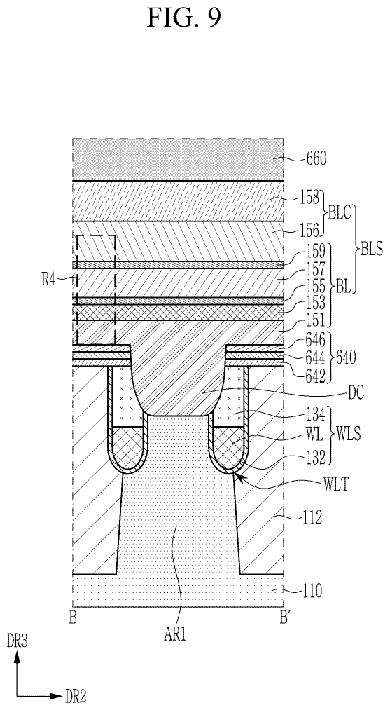

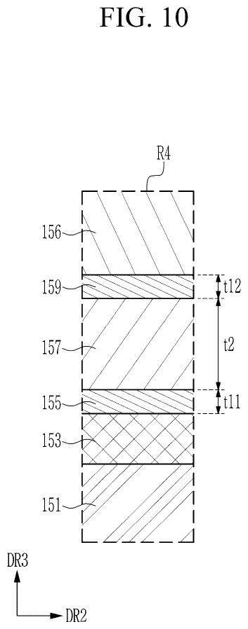

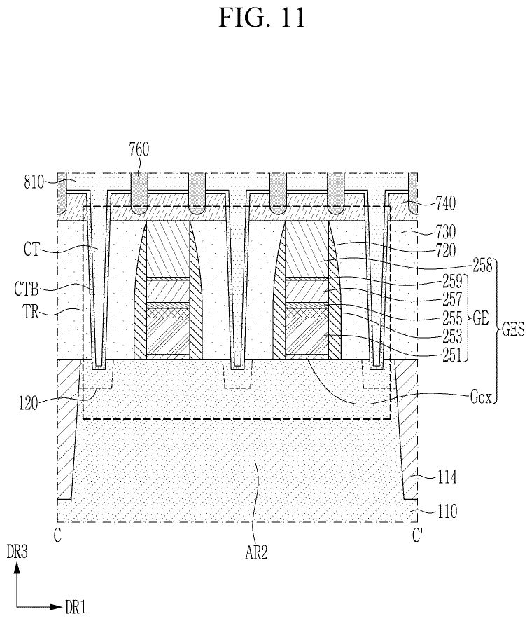

FIG. 8 is a cross-sectional view taken along a line A-A′ of FIG. 2 according to some implementations. FIG. 9 is a cross-sectional view taken along a line B-B′ of FIG. 2 according to some implementations. FIG. 10 is an enlarged cross-sectional view of R4 in FIG. 9 according to some implementations. FIG. 11 is a cross-sectional view taken along a line C-C′ of FIG. 3 according to some implementations. The implementations illustrated in FIGS. 8 to 11 may be substantially identical to the implementations illustrated in FIGS. 4 to 7. In the implementations illustrated in FIGS. 8 to 11, the same components as in the implementations illustrated in FIGS. 4 to 7 may be referenced by the same symbols. Below, the differences between the implementations illustrated in FIGS. 8 to 11 and the implementations illustrated in FIGS. 4 to 7 will be mainly explained. The implementations illustrated in FIGS. 8 to 11 may differ in some respects from the implementations illustrated in FIGS. 4 to 7 in that the bit line BL of the cell region CR further includes a fifth bit line conductive layer 159 and the gate electrode GE of the peripheral circuit region PR further includes a fifth gate conductive layer 259.

In FIGS. 8 and 9, the bit line BL may further include a fifth bit line conductive layer 159 positioned on the fourth bit line conductive layer 157. In some implementations, the third bit line conductive layer 155 may be positioned on the lower surface of the fourth bit line conductive layer 157, and the fifth bit line conductive layer 159 may be positioned on the upper surface of the fourth bit line conductive layer 157. The third bit line conductive layer 155 may cover the lower surface of the fourth bit line conductive layer 157, and the fifth bit line conductive layer 159 may cover the upper surface of the fourth bit line conductive layer 157. The third bit line conductive layer 155 may be in contact with the lower surface of the fourth bit line conductive layer 157, and the fifth bit line conductive layer 159 may be in contact with the upper surface of the fourth bit line conductive layer 157.

In FIGS. 4 to 7, the third bit line conductive layer 155 may include a semiconductor compound of the same metallic material as the fourth bit line conductive layer 157. In some implementations, the fourth bit line conductive layer 157 may include a first metallic material, and the third bit line conductive layer 155 may include a compound of the first metallic material and the first semiconductor material.

In some implementations, the fifth bit line conductive layer 159 may include a compound of a semiconductor material of the same metallic material as the fourth bit line conductive layer 157. In some implementations, the fifth bit line conductive layer 159 may include a compound of the first metallic material and the second semiconductor material. In some implementations, the second semiconductor material may be identical to the first semiconductor material, but is not limited thereto. For example, the first semiconductor material and the second semiconductor material may be Si. For example, the third bit line conductive layer 155 and the fifth bit line conductive layer 159 may include a silicide material of the first metallic material. The third bit line conductive layer 155 may be alternatively referred to as a first metal silicide layer, and the fifth bit line conductive layer 159 may be alternatively referred to as a second metal silicide layer.

The number of the atoms of the second semiconductor material included in the fifth bit line conductive layer 159 may be greater than the number of the atoms of the first metallic material included in the fifth bit line conductive layer 159. For example, the first metallic material may be W and the second semiconductor material may be Si. In some implementations, the fifth bit line conductive layer 159 may include WₘSiₙ, and m<n.

The atom ratio of the first metallic material included in the fifth bit line conductive layer 159 to the second semiconductor material included in the fifth bit line conductive layer 159 may be greater than 1:3 and less than 1:1. For example, the first metallic material may be W and the second semiconductor material may be Si. In some implementations, the fifth bit line conductive layer 159 may include WₘSiₙ, and m:n may be greater than 1:3 to less than 1:1. At this time, the atom ratio of the first metallic material to the second semiconductor material does not only mean the composition ratio of the compound of the first metallic material to the second semiconductor material included in the fifth bit line conductive layer 159, but also means the ratio of the entire number of the atoms of the first metallic material included in the fifth bit line conductive layer 159 to the entire number of the atoms of the second semiconductor material included in the fifth bit line conductive layer 159. That is, it does not mean that the fifth bit line conductive layer 159 includes only compounds in which atoms of the first metallic material and atoms of the second semiconductor material are bonded in a ratio of more than 1:3 and less than 1:1, but rather that the average bonding ratio between atoms of the first metallic material and atoms of the second semiconductor material included in the fifth bit line conductive layer 159 is more than 1:3 and less than 1:1. For example, the fifth bit line conductive layer 159 may include a compound in which atoms of the first metallic material and atoms of the second semiconductor material are combined in a ratio of 1:1 or less or 1:3 or greater. For example, the fifth bit line conductive layer 159 may include WSi₂ or WSi_{1.75}, or may include WSi or WSi₃. However, the average m:n of various WₘSiₙ included in the fifth bit line conductive layer 159 may be greater than 1:3 and less than 1:1.

When the atom ratio (m:n) of the first metallic material to the second semiconductor material included in the fifth bit line conductive layer 159 is greater than 1:1, the stress applied to the fourth bit line conductive layer 157 is not relieved as desired. If the atom ratio (m:n) of the first metallic material to the second semiconductor material included in the fifth bit line conductive layer 159 is 1:3 or less, the resistance of the bit line BL may increase and the electric characteristics of the semiconductor device may deteriorate. In some implementations, the atom ratio (m:n) of the first metallic material to the second semiconductor material included in the fifth bit line conductive layer 159 may be greater than 1:3 and less than 1:1, and preferably, greater than or equal to 1:2.7 and less than or equal to 1:1.5. For example, the atom ratio (m:n) of the first metallic material to the second semiconductor material included in the fifth bit line conductive layer 159 may be 1:1.75.

In FIG. 10, a ratio (t11+t12):t2 of the sum (t11+t12) of the thicknesses of the third bit line conductive layer 155 and the fifth bit line conductive layer 159 to the thickness t2 of the fourth bit line conductive layer 157 may be greater than 1:6 to less than 1:3. If the ratio (t11+t12):t2 of the sum (t11+t12) of the thicknesses of the third bit line conductive layer 155 and the fifth bit line conductive layer 159 and the thickness t2 of the fourth bit line conductive layer 157 is 1:3 or greater, the resistance of the bit line BL may increase, thereby deteriorating the electric characteristics of the semiconductor device. When the ratio (t11+t12):t2 of the sum (t11+t12) of the thicknesses of the third bit line conductive layer 155 and the fifth bit line conductive layer 159 (t11 t12) to the thickness t2 of the fourth bit line conductive layer 157 is 1:6 or less, the stress applied to the fourth bit line conductive layer 157 is not relieved as desired.

In FIG. 11, the gate electrode GE may include a fifth gate conductive layer 259 positioned on the fourth gate conductive layer 257. In some implementations, the third gate conductive layer 255 may be positioned on the lower surface of the fourth gate conductive layer 257, and the fifth gate conductive layer 259 may be positioned on the upper surface of the fourth gate conductive layer 257. The third gate conductive layer 255 may cover the lower surface of the fourth gate conductive layer 257, and the fifth gate conductive layer 259 may cover the upper surface of the fourth gate conductive layer 257. The third gate conductive layer 255 may be in contact with the lower surface of the fourth gate conductive layer 257, and the fifth gate conductive layer 259 may be in contact with the upper surface of the fourth gate conductive layer 257.

In FIGS. 4 to 7, the gate electrode GE may be positioned in the same layer as the bit line BL and may include a layer including the same material. Here, positioning in the same layer as the bit line BL may mean being formed in the same process as each layer of the bit line BL. The first gate conductive layer 251 may be positioned in the same layer and may include the same material as the first bit line conductive layer 151. The second gate conductive layer 253 may be positioned in the same layer and may contain the same material as the second bit line conductive layer 153. The third gate conductive layer 255 may be positioned in the same layer and may include the same material as the third bit line conductive layer 155. The fourth gate conductive layer 257 may be positioned in the same layer and may include the same material as the fourth bit line conductive layer 157. In some implementations, the fifth gate conductive layer 259 may be positioned in the same layer and may include the same material as the fifth bit line conductive layer 159.

In FIGS. 4 to 7, the third gate conductive layer 255 may include a semiconductor compound of the same metallic material as the fourth gate conductive layer 257. In some implementations, the fourth gate conductive layer 257 may include the first metallic material, and the third gate conductive layer 255 may include a compound of the first metallic material and the first semiconductor material.

In some implementations, the fifth gate conductive layer 259 may include a compound of the semiconductor material of the same metallic material as the fourth gate conductive layer 257. In some implementations, the fifth gate conductive layer 259 may include a compound of the first metallic material and the second semiconductor material. In some implementations, the second semiconductor material may be identical to the first semiconductor material, but is not limited thereto. For example, the first semiconductor material and the second semiconductor material may be Si. For example, the third gate conductive layer 255 and the fifth gate conductive layer 259 may include a silicide material of the first metallic material. The third gate conductive layer 255 may be alternatively referred to as the third metal silicide layer, and the fifth gate conductive layer 259 may be alternatively referred to as the second metal silicide layer.

The number of atoms of the second semiconductor material included in the fifth gate conductive layer 259 may be greater than the number of atoms of the first metallic material included in the fifth gate conductive layer 259. For example, the first metallic material may be W and the second semiconductor material may be Si. In some implementations, the fifth gate conductive layer 259 may be WₚSi_{q}, and may be p<q.

The atom ratio of the first metallic material included in the fifth gate conductive layer 259 to the second semiconductor material included in the fifth gate conductive layer 259 can be greater than 1:3 and less than 1:1. For example, the first metallic material may be W and the second semiconductor material may be Si. In some implementations, the fifth gate conductive layer 259 may include WₚSi_{q}, and p:q may be greater than 1:3 to less than 1:1. At this time, the atom ratio of the first metallic material to the second semiconductor material does not only mean the composition ratio of the compound of the first metallic material to the second semiconductor material included in the fifth gate conductive layer 259, but also means the ratio of the entire number of the atoms of the first metallic material included in the fifth gate conductive layer 259 to the entire number of the atoms of the second semiconductor material included in the fifth gate conductive layer 259. That is, it does not mean that the fifth gate conductive layer 259 includes only compounds in which atoms of the first metallic material and atoms of the second semiconductor material are bonded in a ratio of more than 1:3 and less than 1:1, but rather that the average bonding ratio between atoms of the first metallic material and atoms of the second semiconductor material included in the fifth gate conductive layer 259 is more than 1:3 and less than 1:1. For example, the fifth gate conductive layer 259 may include a compound in which atoms of the first metallic material and atoms of the second semiconductor material are combined in a ratio of 1:1 or less or 1:3 or greater. For example, the fifth gate conductive layer 259 may include WSi₂ or WSi_{1.75}, and may include WSi or WSi₃. However, the average p:q of various WₒSi_{q} included in the fifth gate conductive layer 259 may be greater than 1:3 and less than 1:1.

When the atom ratio (p:q) of the first metallic material to the second semiconductor material included in the fifth gate conductive layer 259 is greater than 1:1, the stress applied to the fourth gate conductive layer 257 is not relieved as desired. When the atom ratio (p:q) of the first metallic material to the second semiconductor material included in the fifth gate conductive layer 259 is 1:3 or less, the resistance of the gate electrode GE may increase, deteriorating the electric characteristics of the semiconductor device. In some implementations, the atom ratio (p:q) of the first metallic material to the second semiconductor material included in the fifth gate conductive layer 259 may be greater than 1:3 and less than 1:1, and preferably, greater than or equal to 1:2.7 and less than or equal to 1:1.5. For example, the atom ratio (p:q) of the first metallic material to the second semiconductor material included in the fifth gate conductive layer 259 may be 1:1.75.

The ratio of the sum of the thicknesses of the third gate conductive layer 255 and the fifth gate conductive layer 259 to the thickness of the fourth gate conductive layer 257 may be greater than 1:6 and less than 1:3. When the ratio of the sum of the thicknesses of the third gate conductive layer 255 and the fifth gate conductive layer 259 to the thickness of the fourth gate conductive layer 257 is greater than 1:3, the resistance of the gate electrode GE may increase, thereby deteriorating the electric characteristics of the semiconductor device. When the ratio of the sum of the thicknesses of the third gate conductive layer 255 and the fifth gate conductive layer 259 to the thickness of the fourth gate conductive layer 257 is 1:6 or less, the stress applied to the fourth gate conductive layer 257 is not relieved as desired.

According to some implementations, the warpage problem may be improved by relieving a film stress applied to the bit line BL without increasing the resistance of the bit line BL positioned in the cell region CR.

According to some implementations, the warpage problem may be improved by relieving the film stress applied to the gate electrode GE without increasing the resistance of the gate electrode GE positioned in the peripheral circuit region PR.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device comprising:
a substrate including a first active region;
a word line intersecting the first active region and extending in a first direction; and
a bit line intersecting the word line and extending in a second direction,
wherein the bit line includes:
a first bit line conductive layer including a semiconductor material,
a second bit line conductive layer on the first bit line conductive layer,
a third bit line conductive layer on the second bit line conductive layer, and
a fourth bit line conductive layer on the third bit line conductive layer,
wherein the fourth bit line conductive layer includes a metallic material,
wherein the third bit line conductive layer includes a compound of the metallic material and a first semiconductor material, and
wherein an atom ratio of the metallic material to the first semiconductor material included in the third bit line conductive layer is greater than 1:3 and less than 1:1.

2. The semiconductor device of claim 1, wherein a direction of a stress applied to the fourth bit line conductive layer by the third bit line conductive layer is opposite to a direction of a stress applied to the fourth bit line conductive layer by a plurality of layers positioned between the substrate and the third bit line conductive layer.

3. The semiconductor device of claim 2,
wherein the plurality of layers is configured to apply a compressive stress to the fourth bit line conductive layer, and
wherein the third bit line conductive layer is configured to relieve the compressive stress applied to the fourth bit line conductive layer.

4. The semiconductor device of claim 1, wherein a ratio of a thickness of the third bit line conductive layer to a thickness of the fourth bit line conductive layer is greater than 1:6 and less than 1:3.

5. The semiconductor device of claim 1,
wherein the bit line includes a fifth bit line conductive layer on the fourth bit line conductive layer, and
wherein the fifth bit line conductive layer includes a compound of the metallic material and a second semiconductor material.

6. The semiconductor device of claim 5, wherein a ratio of a sum of thicknesses of the third bit line conductive layer and the fifth bit line conductive layer to a thickness of the fourth bit line conductive layer is greater than 1:6 and less than 1:3.

7. The semiconductor device of claim 1, wherein the second bit line conductive layer includes a material different from the first semiconductor material.

8. The semiconductor device of claim 1,
wherein the substrate includes a cell region including the first active region and a peripheral circuit region surrounding the cell region,
wherein the peripheral circuit region includes a second active region,
wherein the semiconductor device includes a gate electrode intersecting the second active region and extending in the second direction,
wherein the gate electrode includes a layer positioned in a same layer as the bit line; and
wherein the gate electrode comprises a same material as a material of the bit line.

9. The semiconductor device of claim 8, wherein the gate electrode includes:
a first gate conductive layer in a same layer as the first bit line conductive layer;
a second gate conductive layer on the first gate conductive layer and in a same layer as the second bit line conductive layer;
a third gate conductive layer on the second gate conductive layer and in a same layer as the third bit line conductive layer; and
a fourth gate conductive layer on the third gate conductive layer and in a same layer as the fourth bit line conductive layer.

10. The semiconductor device of claim 9,
wherein the first gate conductive layer includes a same material as a material of the first bit line conductive layer,
wherein the second gate conductive layer includes a same material as a material of the second bit line conductive layer,
wherein the third gate conductive layer includes a same material as a material of the third bit line conductive layer, and
wherein the fourth gate conductive layer includes a same material as a material of the fourth bit line conductive layer.

11. A semiconductor device comprising:
a substrate including a first active region;
a word line intersecting the first active region and extending in a first direction; and
a bit line intersecting the word line and extending in a second direction,
wherein the bit line includes:
a first semiconductor layer including a semiconductor material;
a first metal layer on the first semiconductor layer and including a metallic material;
a first interface layer between the first semiconductor layer and the first metal layer; and
a first metal silicide layer covering a lower surface of the first metal layer,
wherein the first metal silicide layer includes a same metallic material as a material of the first metal layer, and
wherein the first metal silicide layer has a greater number of atoms of silicon than a number of atoms of the metallic material.

12. The semiconductor device of claim 11, wherein an atom ratio of the metallic material included in the first metal silicide layer to the silicon included in the first metal silicide layer is greater than 1:3 and less than 1:1.

13. The semiconductor device of claim 11, wherein a thickness ratio of the first metal silicide layer to the first metal layer is greater than 1:6 and less than 1:3.

14. The semiconductor device of claim 11,
wherein the bit line includes a second metal silicide layer covering an upper surface of the first metal layer, and
wherein the second metal silicide layer includes a same metallic material as a material of the first metal layer.

15. The semiconductor device of claim 11,
wherein the substrate includes a cell region including the first active region and a peripheral circuit region surrounding the cell region,
wherein the peripheral circuit region includes a second active region,
wherein the semiconductor device includes a gate electrode intersecting the second active region and extending in the second direction, and
wherein the gate electrode includes a layer including a same material as a material of the bit line.

16. The semiconductor device of claim 15,
wherein the gate electrode includes:
a second semiconductor layer including a same material as a material of the first semiconductor layer;
a second metal layer including a same metallic material as a material of the first metal layer;
a second interface layer including a same material as a material of the first interface layer; and
a third metal silicide layer including a same material as a material of the first metal silicide layer,
wherein the second metal layer is on the second semiconductor layer,
wherein the second interface layer is between the second semiconductor layer and the second metal layer, and
wherein the third metal silicide layer covers a lower surface of the second metal layer.

17. The semiconductor device of claim 16,
wherein the gate electrode includes a fourth metal silicide layer covering an upper surface of the second metal layer, and
wherein the fourth metal silicide layer includes a same material as a material of the third metal silicide layer.

18. A semiconductor device comprising:
a substrate including an active region;
a word line intersecting the active region and extending in a first direction; and
a bit line intersecting the word line and extending in a second direction,
wherein the bit line includes:
a first bit line conductive layer including a semiconductor material;
a second bit line conductive layer on the first bit line conductive layer;
a third bit line conductive layer on the second bit line conductive layer; and
a fourth bit line conductive layer on the third bit line conductive layer,
wherein the fourth bit line conductive layer includes a metallic material,
wherein the third bit line conductive layer includes a compound of the metallic material and a first semiconductor material, and
wherein the second bit line conductive layer includes a material different from a material of the first semiconductor material.

19. The semiconductor device of claim 18, wherein an atom ratio of the metallic material to the first semiconductor material included in the third bit line conductive layer is greater than 1:3 and less than 1:1.

20. The semiconductor device of claim 18, wherein a thickness ratio of the third bit line conductive layer to the fourth bit line conductive layer is greater than 1:6 and less than 1:3.
